(19) United States
(12) Patent Application Publication
(10) Pub. No.: US 2016/0168750 A1
(43) Pub. Date: Jun. 16, 2016

(54) METHOD OF PRODUCING HIGH-PURITY CARBIDE MOLD

(71) Applicant: NATIONAL CHUNG SHAN INSTITUTE OF SCIENCE AND TECHNOLOGY, Longtan Township (TW)

(72) Inventors: DAI-LIANG MA, TAOYUAN CITY (TW); TSAO-CHUN PENG, LONGTAN TOWNSHIP (TW); BANG-YING YU, LONGTAN TOWNSHIP (TW); HSUEH-I CHEN, LONGTAN TOWNSHIP (TW); JUN-BIN HUANG, TAINAN CITY (TW)

(21) Appl. No.: 14/565,456

(22) Filed: Dec. 10, 2014

(51) Int. Cl. C30B 23/06; C30B 25/10; C30B 25/16; C23C 14/00; C23C 16/32; C23C 16/01; C23C 14/06; C01B 31/36; C30B 29/36

(52) U.S. Cl. CPC C30B 23/066; C01B 31/36; C30B 25/10; C30B 25/165; C30B 29/36; C23C 16/325; C23C 16/01; C23C 14/0635; C23C 14/0005

(57) ABSTRACT

A method of producing a high-purity carbide mold includes the steps of (A) providing a template; (B) putting the template at a deposition region in a growth chamber; (C) putting a carbide raw material in the growth chamber; (D) providing a heating field; (E) introducing a gas; (F) depositing the carbide raw material; and (G) removing the template. The method is able to produce a mold from a high-purity carbide with a purity of 93% or above and therefore is effective in solving known problems with carbide molds, that is, low hardness and low purity.

### FIELD OF TECHNOLOGY

The present invention relates to methods of producing a high-purity carbide mold, and more particularly, to a method of producing a high-purity silicon carbide mold.

### BACKGROUND

Conventionally, manufacturers usually produce carbide molds by powder press molding. The carbide molds thus produced have low hardness and low purity. In the situation where a carrier disk is produced with a plated layer, not only is the uniformity and purity of the plated layer difficult to control, but the plating rate is low, not to mention that the thickness of the plated layer is subject to a limit.

Regarding a conventional carbide mold, for example, U.S. Pat. No. 4,606,750 discloses a mold for manufacturing optical glass parts by the direct press molding of lumps of raw optical glass. The pressing surface of the mold is made of a material comprising α-silicon carbide (SiC), amorphous silicon carbide (SiC), or a mixture of both. The pressing surface may be a coated film on a base body of hard alloy or high density carbon. Direct press molding applies to the silicon carbide mold forming method. The substrate is a high density base body of carbon.

In addition, silicon carbide is deposited on a substrate by some methods. For instance, U.S. Pat. No. 6,372,304 discloses that a SiC thin film can be deposited on the surface of a plastic material utilizing Electron Cyclotron Resonance (ECR) Plasma Chemical Vapor Deposition (CVD) techniques, thereby enhancing surfacial hardness of the plastic material. For instance, CN 100564255 discloses turning an organometallic polymer into a precursor by precursor conversion, shaping the precursor in accordance with its characteristics, such as being soluble and fusible, and turning the precursor from an organic matter into an inorganic ceramic by a high-temperature thermal decomposition process. However, the aforesaid methods are restricted to depositing silicon carbide on a substrate and therefore fail to form high-purity carbide molds.

### SUMMARY

In view of the aforesaid drawbacks of the prior art, the present invention provides a method of producing a high-purity carbide mold with a view to solving known problems, such as low hardness and low purity of carbide molds.

In order to achieve the above and other objectives, the present invention provides a method of producing a high-purity carbide mold, comprising the steps of: (A) providing a template made of a carbon high-temperature material; (B) putting the template in a growth chamber, wherein a surface of the template functions as a deposition surface which a carbide raw material deposits on; (C) putting the carbide raw material in the growth chamber, wherein the carbide raw material and the template are disposed at two opposing ends of the growth chamber, respectively; (D) providing a heating field, wherein the heating field is provided for the growth chamber by a heating field device enclosing the growth chamber, wherein a location of the heating field device is adjusted to allow the carbide raw material to be positioned at a relatively hot end of the heating field, allow the carbide raw material to sublime because of the heating field, and allow the template to be positioned at a relatively cold end of the heating field, wherein temperature of the heating field ranges from room temperature to 3000° C., and temperature gradient of the heating field is 2.5-100° C./cm or above; (E) introducing a gas, including introducing an inert gas into the growth chamber; (F) depositing the carbide raw material, wherein the location of the heating field device is continually adjusted to allow the carbide raw material to sublime because of the heating field as recited in step (D), thereby depositing gaseous said carbide raw material on the deposition surface of the template; and (G) removing the template by high-temperature oxidation.

Regarding the method, the mold is produced from a high-purity carbide with a purity of 93% or above, wherein the high-purity carbide is monocrystalline or polycrystalline.

Regarding the method, the carbon high-temperature material includes c-c composite, highly isotropic graphite, high-purity graphite, or medium-to-high-purity graphite lumps, and a monocrystalline silicon carbide wafer.

Regarding the method, the deposition surface is polygonal, round, annular, rectangular, curved, irregularly patterned, needle-shaped, reticular, sloping, or steplike, wherein diametrical, radial, and axial lengths of the template are less than 500 mm

Regarding the method, the inert gas comprises one selected from the group consisting of high-purity argon gas (Ar) and high-purity nitrogen gas (N₂).

Regarding the method, in step (E), an auxiliary gas which comprises one selected from the group consisting of hydrogen gas (H₂), methane (CH₄), and ammonia (NH₃) is introduced.

Regarding the method, in step (F), the carbide raw material deposits on the deposition surface by physical vapor transport (PVT), physical vapor deposition (PVD), or chemical vapor deposition (CVD).

Regarding the method, in step (F), the deposition rate of the carbide raw material is 10 nm/hr˜1000 nm/hr.

Regarding the method, step (G), the high-temperature oxidation occurs at 900˜1200° C.

According to the present invention, a method of producing a high-purity carbide mold is able to produce a mold comprising a high-purity carbide with a purity of 93% or above and therefore is effective in solving known problems with carbide molds, that is, low hardness and low purity.

### BRIEF DESCRIPTION

Objectives, features, and advantages of the present invention are hereunder illustrated with specific embodiments in conjunction with the accompanying drawings, in which:

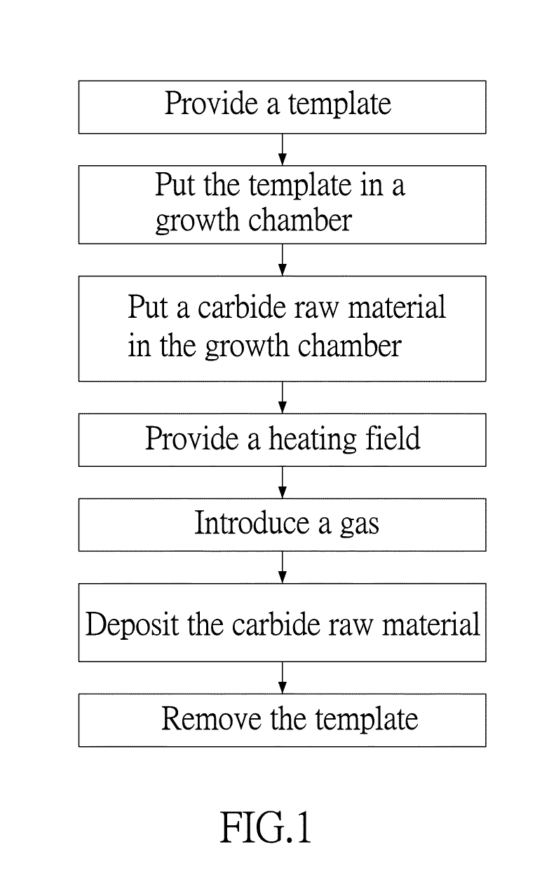

FIG. 1 is a flowchart of a method of producing a high-purity carbide mold according to the present invention;

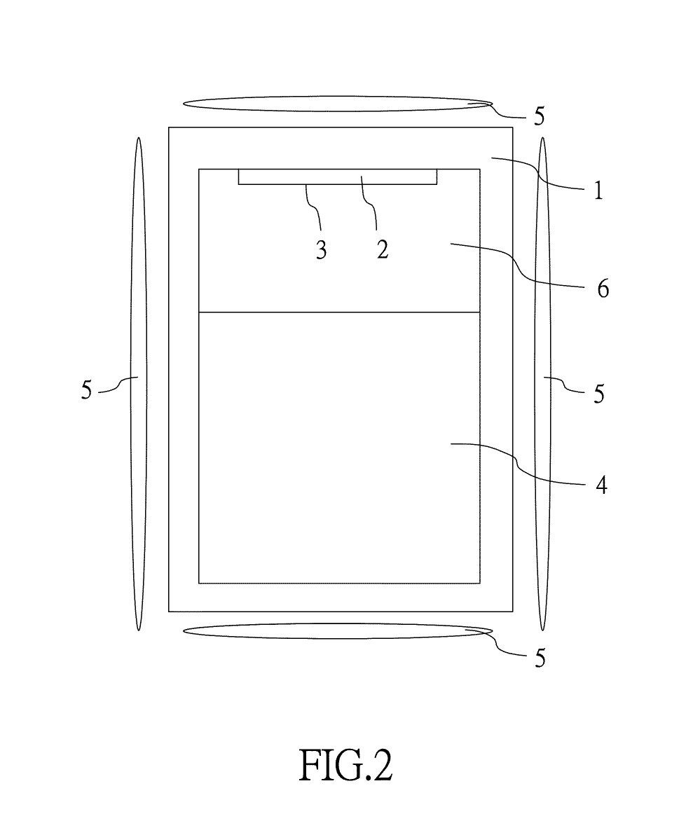

FIG. 2 is a schematic view of an apparatus for producing a high-purity carbide mold according to the present invention;

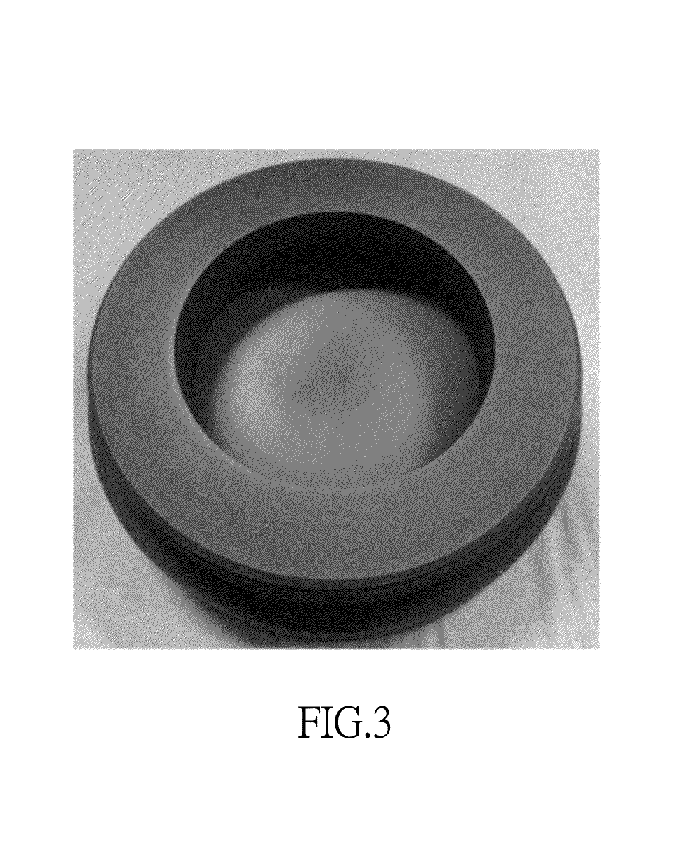

FIG. 3 is a picture of a 2-inch disk-shaped high-purity graphite template according to embodiment 1 of the present invention;

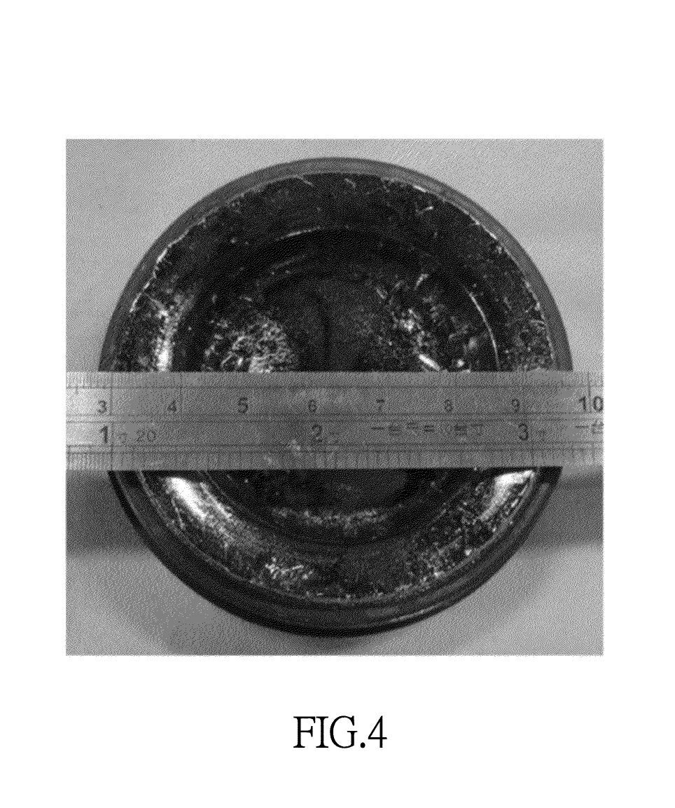

FIG. 4 is a picture of monocrystalline silicon carbide deposited on the 2-inch disk-shaped template according to embodiment 1 of the present invention;

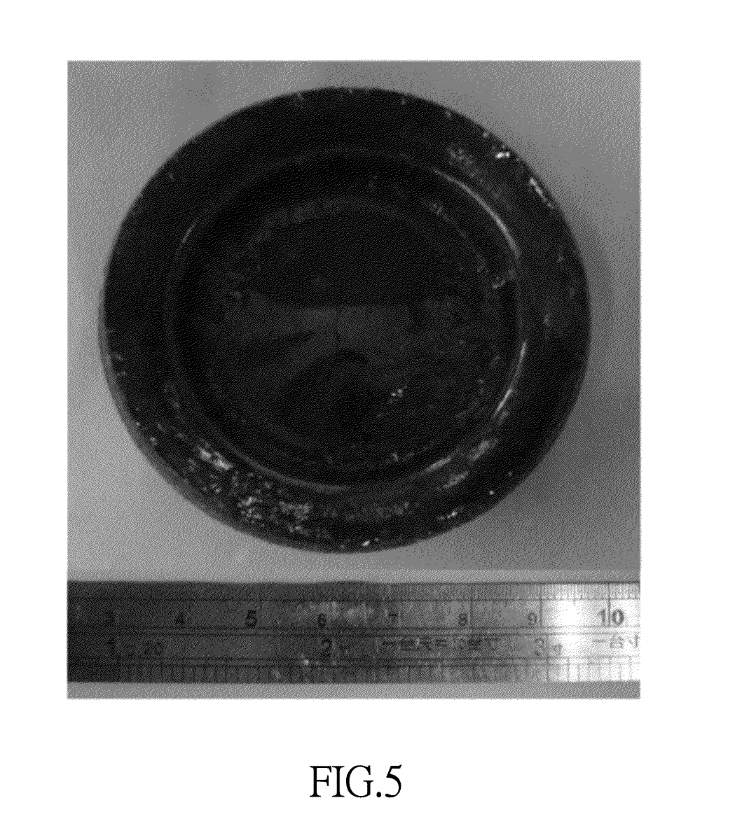

FIG. 5 is a top view of the 2-inch monocrystalline disk-shaped mold according to embodiment 1 of the present invention;

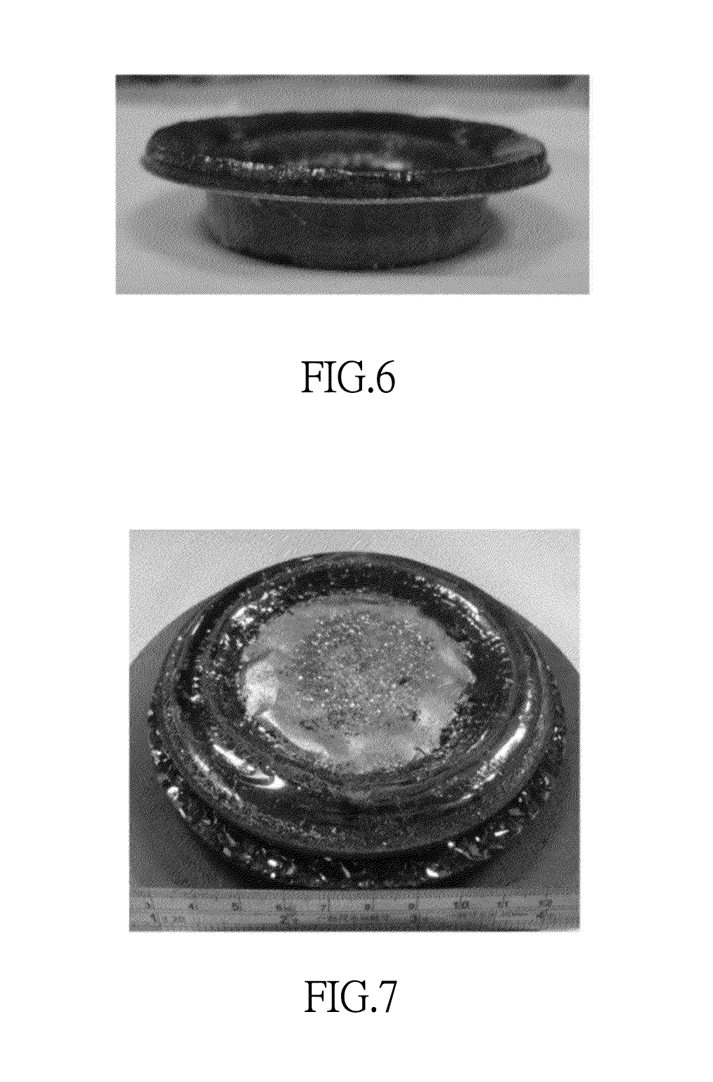

FIG. 6 is a side view of the 2-inch monocrystalline disk-shaped mold according to embodiment 1 of the present invention;

FIG. 7 is a picture of silicon carbide deposited on a 4-inch annular curved template according to embodiment 2 and embodiment 3 of the present invention;

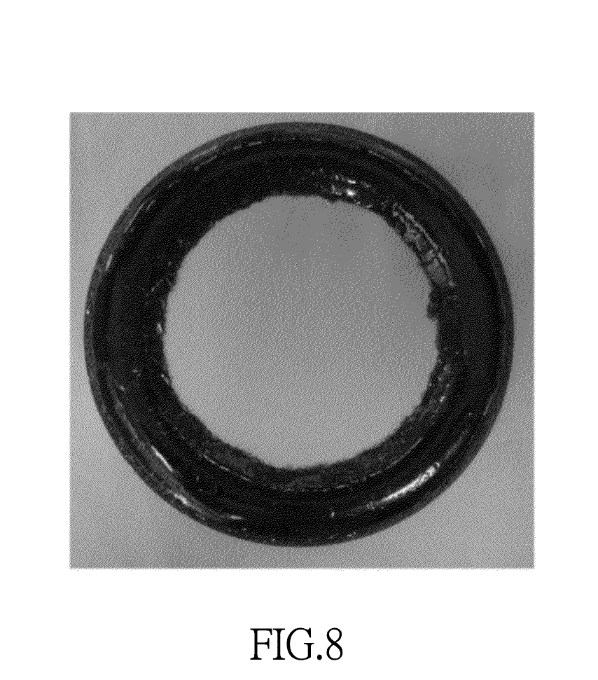

FIG. 8 is a picture of a 4-inch monocrystalline annular curved mold produced according to embodiment 2 of the present invention;

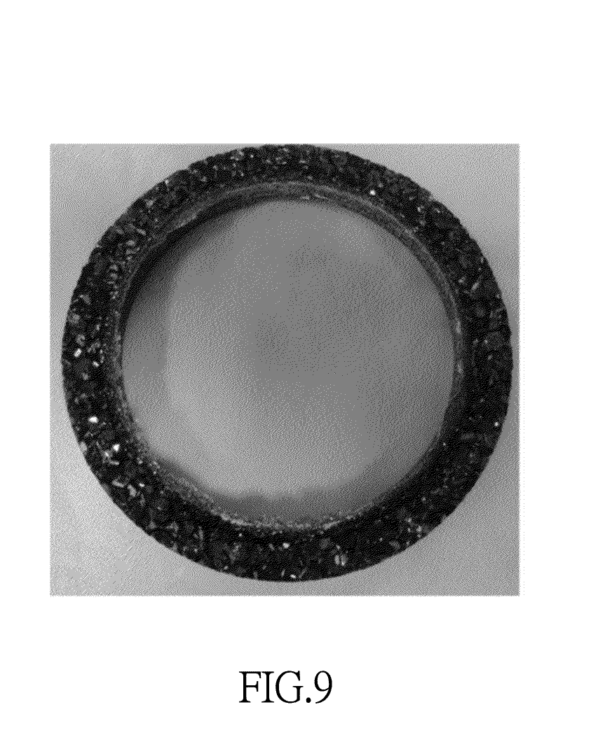

FIG. 9 is a picture of a 4-inch polycrystalline annular mold produced according to embodiment 3 of the present invention;

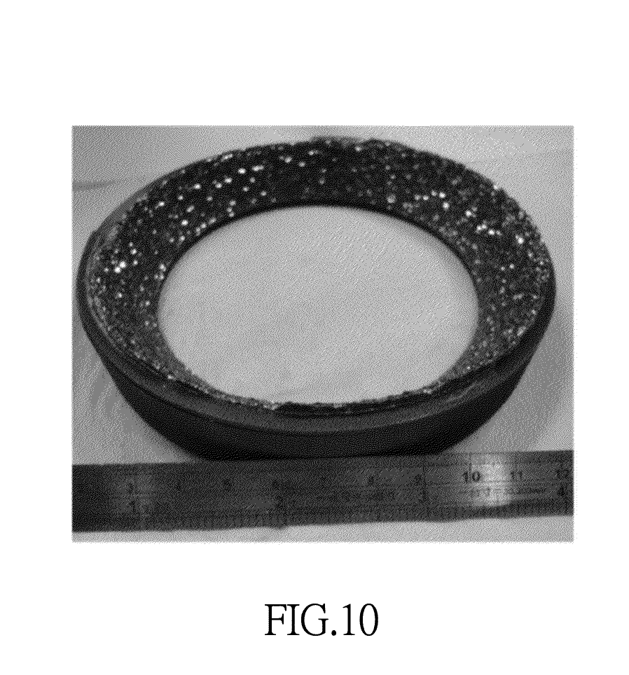

FIG. 10 is a picture of polycrystalline silicon carbide deposited on a 4-inch sloping annular template according to embodiment 4 of the present invention; and

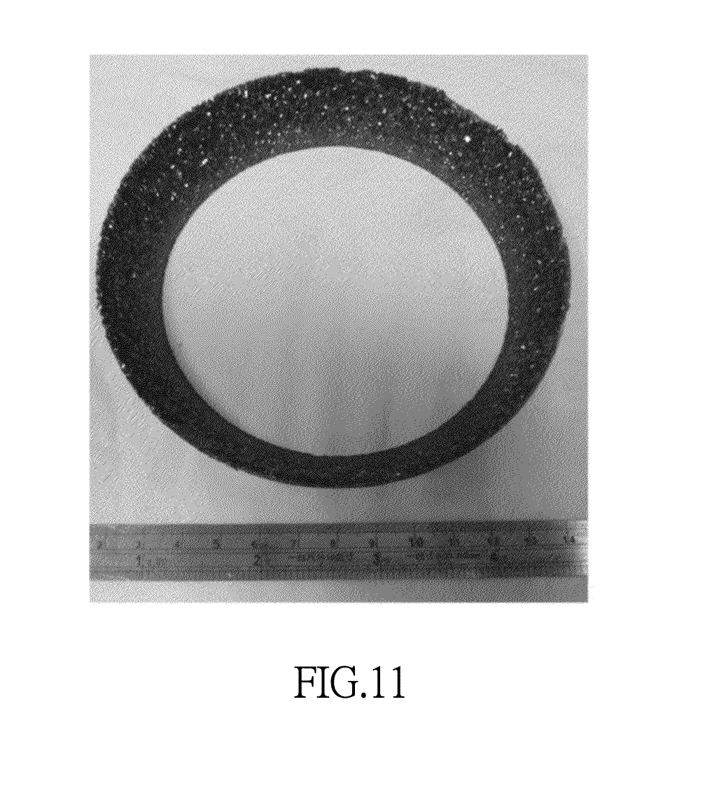

FIG. 11 is a picture of a 4-inch polycrystalline sloping annular mold produced according to embodiment 4 of the present invention.

### DETAILED DESCRIPTION

The present invention entails adjusting the location of a heating field device which provides temperature gradient and encloses a growth chamber to position a carbide raw material at a relatively hot end of the heating field, such that the carbide raw material sublimes. Then, a template, which has regular or irregular patterns and is intended to be plated, is positioned at a relatively cold end of the heating field. Afterward, the temperature, heating field, atmosphere, and pressure in the heating field device are controlled in a manner that the gaseous carbide raw material is delivered and deposited on the template positioned at the relatively cold end. Given a deposition rate of 10 mm/hr˜1000 μm/hr, a deposit thickness of 10 μm˜3 cm is attained in a short period of time. Eventually, a substrate is peeled off by high-temperature oxidation to meet the specifications and requirements of a high-purity mold.

According to the present invention, the process flow of the method of producing a high-purity carbide mold is shown in FIG. 1, comprising: (A) providing a template; (B) putting the template at a deposition region in a growth chamber; (C) putting a carbide raw material in the growth chamber; (D) providing a heating field; (E) introducing a gas; (F) depositing the carbide raw material; and (G) removing the template. The steps are described below.

(A) Provide a Template

The template is made of a carbon high-temperature material like c-c composite, highly isotropic graphite, high-purity graphite, or medium-to-high-purity graphite lumps, and a monocrystalline silicon carbide wafer. The deposition surface of the template can, for example, be but not limited to: 1. polygonal; 2. round, annular; 3. rectangular, curved; 4. irregularly patterned; and 5. needle-shaped, reticular, or steplike, depending on the shape of the mold to be produced, wherein diametrical, radial, and axial lengths of the template are less than 500 mm.

(B) Put the Template in a Growth Chamber

The growth chamber used in step (B) is shown in FIG. 2. Step (B) entails putting the template (2) in the growth chamber (1), wherein a surface of the template (2) functions as the deposition surface (3) which a carbide raw material (4) deposits on.

(C) Put the Carbide Raw Material in the Growth Chamber

Referring to FIG. 2, step (C) entails putting the carbide raw material (4) in the growth chamber (1), wherein the carbide raw material (4) and the template (2) are disposed at two opposing ends of the growth chamber (1), respectively. The carbide raw material is silicon carbide, but it is not restrictive of the present invention.

(D) Provide a Heating Field

Referring to FIG. 2, step (D) entails providing a heating field for the growth chamber (1) by a heating field device (5) enclosing the growth chamber (1), wherein a location of the heating field device (5) is adjusted to allow the carbide raw material (4) to be positioned at a relatively hot end of the heating field, allow the carbide raw material (4) to sublime because of the heating field, and allow the template, which has regular or irregular patterns and is intended to be plated, to be positioned at a relatively cold end of the heating field, wherein temperature of the heating field ranges from room temperature to 3000° C. , and temperature gradient of the heating field is 2.5-100° C. /cm or above.

(E) Introduce a Gas

Step (E) entails introducing a gas into the growth chamber and forming a gas temperature gradient control region (6) in the growth chamber (1). The gas thus introduced includes an inert gas like high-purity argon gas (Ar) or nitrogen gas (N₂), and an auxiliary gas like hydrogen gas (H₂), methane (CH₄), or ammonia (NH₃).

(F) Deposit the Carbide Raw Material

Step (F) entails adjusting the location of the heating field device (5) continually to allow the growth chamber (1) to maintain the heating field recited in step (D) and cause the carbide raw material (4) to sublime and deposit on a deposition surface (3) of the template (2). The carbide raw material (4) deposits on the deposition surface (3) primarily by physical vapor transport (PVT) and secondarily by physical vapor deposition (PVD) and chemical vapor deposition (CVD). The deposition rate is 10 μm/hr˜1000 μm/hr, attaining a deposit thickness of 10 μm˜3 cm in a short period of time.

(G) Remove the Template

Step (G) entails removing the template by high-temperature oxidation. The high-temperature oxidation occurs at 900˜1200° C., preferably 1200° C. or above, and lasts 0.5-10 hours, preferably 10 hours or above, during which the carbon-containing template is singed 1 to 10 times to eventually obtain a mold which has a purity 93% or above and is dense, hard, and brittle.

The high-purity carbide mold in embodiments 1-4 described below is produced with a radio-frequency induction furnace, wherein a gas partial pressure and temperature control process entails heating with a power output to increase the temperature to 1800˜2000° C., such that the carbide raw material absorbs heat to accumulate latent heat. Afterward, the gas pressure decreases to 90˜150 torr, so as for the template surface to undergo nucleation for 3˜5 hours. At 2200° C., the gas pressure decreases again to have a low pressure ≦5 torr, such that the high-purity silicon carbide grows rapidly. The gas comprises primarily argon gas with a flow rate of 300 m1/hr and secondarily nitrogen gas with a flow rate of 20 ml/hr.

Embodiment 1: production of a 2-inch monocrystalline disk-shaped mold

In embodiment 1, a 2-inch monocrystalline disk-shaped mold is produced by following the aforesaid steps (A)˜(G), using a 2-inch disk-shaped template shown in FIG. 3, and using silicon carbide as the carbide raw material. Upon completion of steps (A)˜(F), monocrystalline silicon carbide deposits on the template as shown in FIG. 4. Step (G) entails removing the template by high-temperature oxidation. The 2-inch monocrystalline disk-shaped mold thus produced is shown in FIG. 5 and FIG. 6.

Embodiment 2: production of a 4-inch monocrystalline annular curved mold

Although embodiment 2 uses the same method as embodiment 1 does, embodiment 2 uses a 4-inch annular curved template. Upon completion of steps (A)˜(F), silicon carbide deposits on the template as shown in FIG. 7. FIG. 7 shows that silicon carbide deposits on both the inner side and outer side of the template. The template has been removed by high-temperature oxidation by the end of step (G), a 4-inch monocrystalline annular curved mold formed from the silicon carbide deposited on the inner side of the template is shown in FIG. 8.

Embodiment 3: production of a 4-inch polycrystalline annular mold

In embodiment 2, the template has been removed by high-temperature oxidation by the end of step (G), a 4-inch polycrystalline annular mold formed from the silicon carbide deposited on the outer side of the template is shown in FIG. 9. In embodiment 2 and embodiment 3 of the present invention, a single template is used, and silicon carbide is deposited on the inner and outer sides of the template to form two different molds.

Embodiment 4: production of a 4-inch polycrystalline sloping annular mold

Although embodiment 4 uses the same method as embodiment 1 does, embodiment 4 uses a 4-inch sloping annular template. Upon completion of steps (A)˜(F), polycrystalline silicon carbide deposits on the template as shown in FIG. 10. The template has been removed by high-temperature oxidation by the end of step (G), and the 4-inch polycrystalline sloping annular mold thus produced is shown in FIG. 11.

According to the present invention, the shape of a monocrystalline silicon carbide template is effective in controlling the shape, size, and scope of the monocrystalline region in the mold such that a monocrystalline mold will grow, provided that the monocrystalline template is more than 350 μm thick. The shape of a graphite template is effective in controlling the shape, size, and scope of the polycrystalline region in the mold.

A test is performed on the mold produced with the method of producing a high-purity carbide mold according to the present invention, showing that it has a purity of 99.99% or above, Moh's hardness of 13, Vickers microhardness of 25000 kg /mm², surface roughness <5×10³ nm, pH tolerance at 2<pH<13, high-temperature operating temperature of 1500° C. or above, and coefficient of thermal expansion of 4.0×10⁻⁶/K, and therefore it is applicable to the manufacturing of a high-purity silicon carbide mold or mold casing, optical part-oriented high-precision mold or mold casing, abrasion-resistant heat-resistant mold or mold casing, or high-thermal-conductivity mold or mold casing required for a semiconductor process. Compared with conventional carbide molds, the mold produced with the method of producing a high-purity carbide mold according to the present invention manifests better characteristics.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A method of producing a high-purity carbide mold, comprising the steps of:
(A) providing a template made of a carbon high-temperature material;
(B) putting the template in a growth chamber, wherein a surface of the template functions as a deposition surface which a carbide raw material deposits on;
(C) putting the carbide raw material in the growth chamber, wherein the carbide raw material and the template are disposed at two opposing ends of the growth chamber, respectively;
(D) providing a heating field, wherein the heating field is provided for the growth chamber by a heating field device enclosing the growth chamber, wherein a location of the heating field device is adjusted to allow the carbide raw material to be positioned at a relatively hot end of the heating field, allow the carbide raw material to sublime because of the heating field, and allow the template to be positioned at a relatively cold end of the heating field, wherein temperature of the heating field ranges from room temperature to 3000° C., and temperature gradient of the heating field is 2.5-100° C./cm or above;
(E) introducing a gas, including introducing an inert gas into the growth chamber;
(F) depositing the carbide raw material, wherein the location of the heating field device is continually adjusted to allow the carbide raw material to sublime because of the heating field as recited in step (D), thereby depositing gaseous said carbide raw material on the deposition surface of the template; and
(G) removing the template by high-temperature oxidation.

2. The method of claim 1, wherein the mold is produced from a high-purity carbide with a purity of 93% or above, wherein the high-purity carbide is monocrystalline or polycrystalline.

3. The method of claim 1, wherein the a carbon high-temperature material is one of c-c composite, highly isotropic graphite, high-purity graphite, and medium-to-high-purity graphite lumps.

4. The method of claim 1, wherein the deposition surface is polygonal, round, annular, rectangular, curved, irregularly patterned, needle-shaped, reticular, sloping, or steplike, wherein diametrical, radial, and axial lengths of the template are less than 500 mm.

5. The method of claim 1, wherein the inert gas comprises one selected from the group consisting of high-purity argon gas (Ar) and high-purity nitrogen gas (N₂).

6. The method of claim 5, wherein, in step (E), an auxiliary gas which comprises one selected from the group consisting of hydrogen gas (H₂), methane (CH₄), and ammonia (NH₃) is introduced.

7. The method of claim 1, wherein, in step (F), the carbide raw material deposits on the deposition surface by one of physical vapor transport (PVT), physical vapor deposition (PVD), and chemical vapor deposition (CVD).

8. The method of claim 1, wherein, in step (F), a deposition rate of the carbide raw material is 10 μm/hr˜1000 μm/hr.

9. The method of claim 1, wherein, in step (G), the high-temperature oxidation occurs at 900˜1200° C.
